(19) United States
(12) Patent Application Publication
(10) Pub. No.: US 2006/0095817 A1
(43) Pub. Date: May 4, 2006

(54) Buffer for testing a memory module and method thereof

(76) Inventors: Kee-Hoon Lee, Suwon-si (KR); Seung-Man Shin, Suwon-si (KR)

Correspondence Address: HARNESS, DICKEY & PIERCE, P.L.C., P.O. BOX 8910, RESTON, VA, 20195, US

(21) Appl. No.: 11/260,318

(22) Filed: Oct. 28, 2005

(30) Foreign Application Priority Data
Nov. 4, 2004 (KR) 2004-89218

(51) Int. Cl. G11C 29/00

(52) U.S. Cl. 714/719

(57) ABSTRACT

In a method, a test pattern and an associated input mode may be received where the input mode may indicate a manner of applying the test pattern. An output test pattern is applied to at least one of a plurality of memory interface pins in accordance with the input mode. In a buffer, a test register may be configured to receive and store a test pattern and an associated input mode where the input mode may indicate a manner of applying the test pattern. The buffer may further include a test pattern generator configured to repeatedly generate an output test pattern based on the associated input mode.

### PRIORITY STATEMENT

This application claims priority under 35 USC §119 to Korean Patent Application No. 2004-89218, filed on Nov. 4, 2004, the contents of which are herein incorporated by reference in their entirety for all purposes.

### BACKGROUND OF THE INVENTION

1. Field of the Invention

Example embodiments of the present invention relate generally to a buffer of a memory module and method thereof, and more particular to a buffer for testing a memory module and method thereof.

1. Description of the Related Art

A memory module having a plurality of chips mounted on a printed circuit board (PCB) may be classified as a single in-line memory module (SIMM) or a dual in-line memory module (DIMM). A SIMM may be a memory module having memory chips mounted on a single side of a PCB and a DIMM may be a memory module having memory chips mounted on both sides of the PCB.

The DIMM may be further classified as a registered DIMM (RDIMM) or a fully buffered DIMM (FBDIMM). The FBDIMM may operate in accordance with a packet protocol, which may enable higher-speed operation and/or a higher capacity as compared to the RDIMM.

Signal integrity may be a factor taken into account in the design of higher-speed digital systems. Signal integrity design criteria may include performance degradation due to a distortion of a signal waveform. Signal integrity design criteria may be represented as errors due to a crosstalk, timing dependency on the crosstalk, a voltage drop in a power supply voltage, etc.

Crosstalk may refer to a phenomenon where a signal transmitted through one of a plurality of channels may cause undesired noise in a neighboring or adjacent channel due to a cross-coupling capacitance. Conventional methods for reducing the incidence or severity of crosstalk may include extending signal lines and placing a blocking film between the signal lines. However, crosstalk may remain a factor of consideration in the design of higher-speed digital systems.

Signal integrity may also affect memory system operation. As an operating speed of a memory device and/or a memory module increases, the signal integrity of signals within the memory device/module may have a greater effect on operational performance. Characteristics of memory systems known to be related to signal integrity may be monitored to increase a reliability of the memory systems.

FIG. 1 is a block diagram illustrating a conventional FBDIMM 100. Referring to FIG. 1, the FBDIMM 100 may include a plurality of memory chips 110 and a buffer 120. The buffer 120 may include an advanced memory buffer (AMB). The buffer 120 may convert a received packet having a higher data rate into a memory command, may interface with the plurality of memory chips 110 and may perform data transmission between the plurality of memory chips 110.

A buffer (e.g., buffer 120 of FIG. 1) of a memory module may include an embedded test circuit to perform testing of the installed memory during a system initialization and/or a system boot. Embedded test circuits may be referred to as built-in self-test (BIST) circuits. A testing program may be stored in the BIST circuit, which may be built into the buffer, so that the memory module may be tested. When a BIST circuit is used, the memory module may be tested with a relatively small number of pins, and a higher data-rate memory may be tested with a lower-speed test device. BIST circuits may also test a plurality of memory modules in parallel. However, adjusting the test program stored in the BIST circuit may be problematic in conventional memory systems.

Conventional BIST circuits may generate a test pattern and may output the test pattern to the memory as pseudo random bit data. Typically, the pseudo random bit data may not be capable of external control and may rather be based only on portions embedded on the memory module. Further, conventional BIST circuits may have address limitations such that not all addresses of the tested memory modules may be tested.

Memory modules may also be tested with a transparent mode test. In the transparent mode test, test signals may be received from external test equipment (e.g., not embedded on the memory module) and may be transferred to the memory module via the memory buffer. Thus, in the transparent mode test, test patterns may be controlled by external test equipment.

A signal integrity test may be a test performed on a PCB. The signal integrity test may be repeatedly performed using a given test pattern. However, if a BIST is used to perform the signal integrity test, the tested memory modules may be limited to a fixed test pattern (e.g., as stored in the embedded memory) which may make the test less reliable for predicting the performance of the tested memory modules. Further, if the transparent mode test is performed to reduce the afore-mentioned problem of BIST circuits, the signals received from the test equipment may be input directly to memory, which may potentially cause a difference between a pin number in the tested memory module and a pin number designated for testing the memory module, which may thereby reduce a reliability of the transparent mode test.

### SUMMARY OF THE INVENTION

An example embodiment of the present invention is directed to a method of testing a memory module, including receiving a test pattern and an associated input mode, the input mode indicating a manner of applying the received test pattern and applying an output test pattern to at least one of a plurality of memory interface pins in accordance with the input mode.

Another example embodiment of the present invention is directed to a buffer of a memory module, including a test register configured to receive and store a test pattern and an associated input mode, the input mode indicating a manner of applying the test pattern and a test pattern generator configured to repeatedly generate an output test pattern based on the associated input mode.

### BRIEF DESCRIPTION OF THE DRAWINGS

The accompanying drawings are included to provide a further understanding of the invention, and are incorporated in and constitute a part of this specification. The drawings illustrate example embodiments of the present invention and, together with the description, serve to explain principles of the present invention.

FIG. 1 is a block diagram illustrating a conventional fully buffered dual in-line memory module (FBDIMM).

FIG. 2 is a flowchart diagram illustrating a signal testing method according to an example embodiment of the present invention.

FIG. 3 is a block diagram illustrating a memory module according to another example embodiment of the present invention.

FIG. 4 is a schematic view illustrating a bit configuration of a signal integrity test register according to another example embodiment of the present invention.

FIG. 5 is a flowchart diagram illustrating an operation of a test pattern generator according to another example embodiment of the present invention.

FIG. 6 is a waveform diagram of a data pattern applied to a memory interface pin using a signal integrity test register according to another example embodiment of the present invention.

FIG. 7 is a waveform diagram of another data pattern applied to a memory interface pin using a signal integrity test register according to another example embodiment of the present invention.

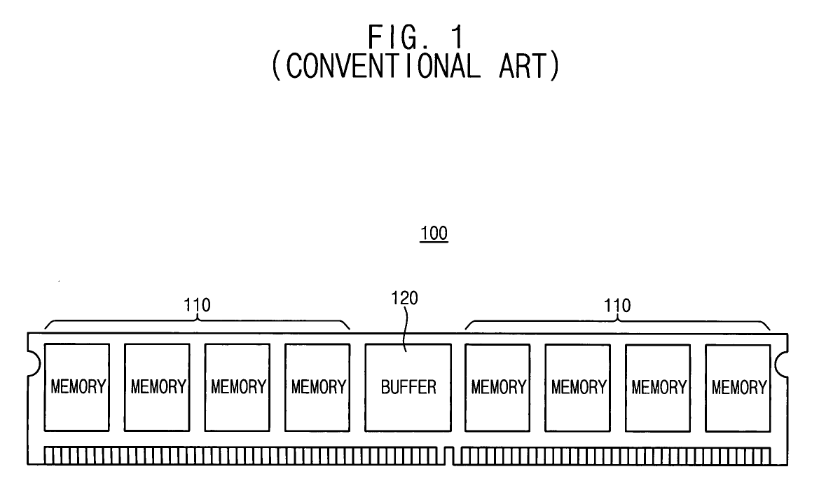

### DETAILED DESCRIPTION OF EXAMPLE EMBODIMENTS OF THE PRESENT INVENTION

Hereinafter, example embodiments of the present invention will be explained in detail with reference to the accompanying drawings.

It will be understood that, although the terms first, second, etc. may be used herein to describe various elements, these elements should not be limited by these terms. These terms are only used to distinguish one element from another. For example, a first element could be termed a second-element, and, similarly, a second element could be termed a first element, without departing from the scope of the present invention. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (i.e., “between” versus “directly between”, “adjacent” versus “directly adjacent”, etc.).

The terminology used herein is for the purpose of describing particular example embodiments only and is not intended to be limiting of the invention. As used herein, the singular forms “a”, “an” and “the” are intended to include the plural forms as well, unless the context clearly indicates otherwise. It will be further understood that the terms “comprises”, “comprising”, “includes” and/or “including”, when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

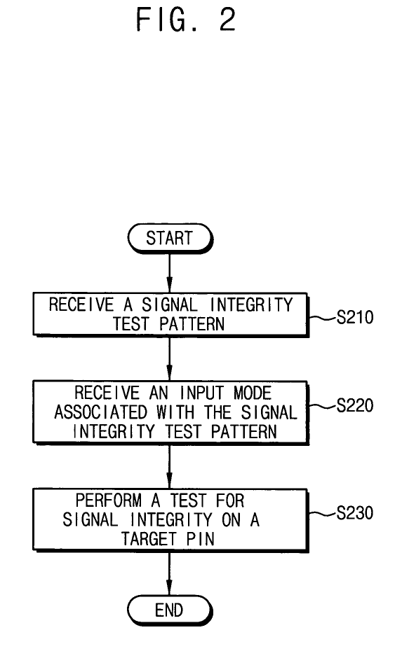

FIG. 2 is a flowchart diagram illustrating a signal testing method according to an example embodiment of the present invention.

In the example embodiment of FIG. 2, a signal integrity test pattern to be applied to a memory module may be received (at S210). The signal integrity test pattern may be a bit pattern or sequence for testing signal integrity of a target pin (e.g., from among memory interface pins in the memory module). In an example, the signal integrity test pattern may received through a system management bus (SMBUS).

In the example embodiment of FIG. 2, an input mode for applying the signal integrity test pattern (received at S210) in the memory module may be received (at S220). In an example, the input mode may designate that the signal integrity test pattern is applied to a target pin at a first logic level (e.g., a higher logic level, a lower logic level, etc.) where the first logic level may also be applied to a pin other than the target pin. In another example, the input mode may designate that the signal integrity test pattern is applied to a target pin at a first logic level (e.g., a higher logic level, a lower logic level, etc.) where a second logic level (e.g., a lower logic level, a higher logic level, etc.) may be applied to a pin other than the target pin.

In the example embodiment of FIG. 2, the first logic level (e.g., a higher logic level or logic “1”) may be assigned to a bit corresponding to a pin to which the signal integrity test pattern may be applied among a plurality of memory interface pins, and the second logic level (e.g., a lower logic level or logic “0”) may be assigned to a bit corresponding to a pin to which an inverted test pattern may be received.

In an alternative example embodiment of FIG. 2, the second logic level (e.g., a lower logic level or logic “0”) may be assigned to a bit corresponding to a pin to which the test pattern may be applied among the plurality of memory interface pins, and the first logic level (e.g., a higher logic level or logic “1”) may be assigned to a bit corresponding to a pin to which an inverted test pattern may be received.

In the example embodiment of FIG. 2, while the order of S210 and S220 are illustrated as being sequential with S220 following S210, it is understood that other example embodiments may be directed to S210 following S220. Further, it is understood that other example embodiments of the present invention may be directed to performing S210 and S220 simultaneously and/or concurrently (e.g., where at least a portion of S210 may overlap with S22). Thus, any order in the Figures or detailed description thereof is given merely for example purposes, and is not meant to imply that example embodiments of the present invention are limited to the order described and/or illustrated.

In the example embodiment of FIG. 2, a test signal may be generated based on the received signal integrity test pattern (at S210) and may be output according to the received input mode (at S220) of the signal integrity test pattern to the memory interface pins so as to test signal integrity of the target pin (at S230).

In another example embodiment of the present invention, referring to FIG. 2, the received signal integrity test pattern and/or an inverted signal integrity test pattern (e.g., inverted from the received signal integrity test pattern) may be repeatedly output to the target pin. Further, according to the input mode of the signal integrity test pattern, the received signal integrity test pattern and/or the inverted signal integrity test pattern may be repeatedly output to a pin other than the target pin. In an example, the memory interface pins may be coupled to a buffer of the memory module.

In the example embodiment of FIG. 2, the memory interface pins may include a DQ pin, an address input pin, a CS input pin, a /CAS input pin, a /RAS input pin, and/or other interface pins. The received signal integrity test pattern and/or the inverted signal integrity test pattern may be applied to all other of the memory interface pins in addition to the target pin. In an alternative example embodiment of FIG. 2, the received signal integrity test pattern and/or the inverted signal integrity test pattern may be applied to less than all of the memory interface pins, for example, pins located in a given proximity of the target pin.

In the example embodiment of FIG. 2, the signal integrity test (at S230) may be performed by measuring a waveform (e.g., by using an oscilloscope) at the target pin. Based on the measured waveform, simultaneous switching noise (SSN), crosstalk and/or inter-symbol interference (ISI) may be determined.

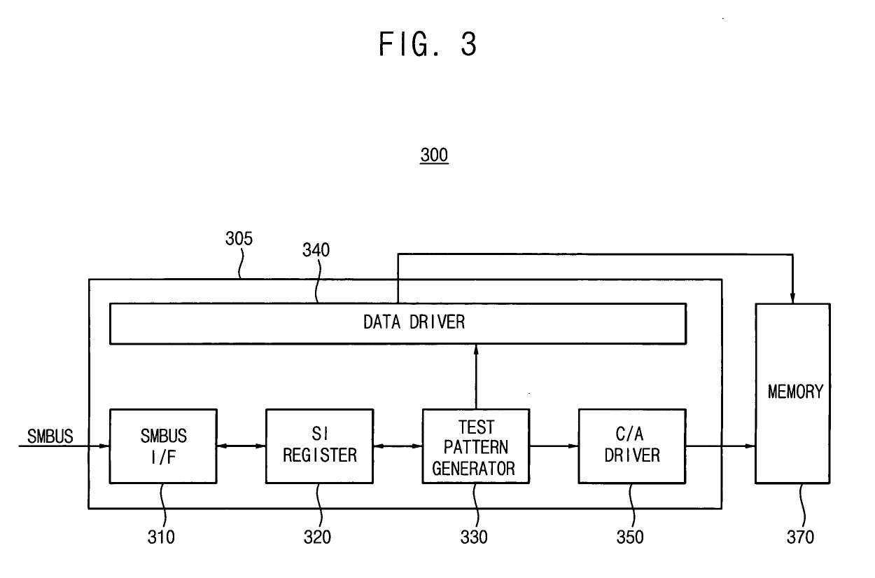

FIG. 3 is a block diagram illustrating a memory module 300 according to another example embodiment of the present invention.

In the example embodiment of FIG. 3, the memory module 300 may include a buffer 305 and a memory 370. In an example, the memory 370 may be a DRAM. The buffer 305 may include a system management bus (SMBUS) interface SMBUS I/F 310, a signal integrity test register SI REGISTER 320, a test pattern generator 330, a data driver 340 and a command/address driver C/A DRIVER 350.

In the example embodiment of FIG. 3, the system management bus interface SMBUS I/F 310 may manage an interface between a system management bus (SMBUS) and a buffer of the memory module. The signal integrity test register SI REGISTER 320 may store the signal integrity test pattern (e.g., received at S210 of FIG. 2) and an input mode associated with the signal integrity test pattern (e.g., received at S220 of FIG. 2) in a test pattern register and a test pattern input mode register, respectively.

In the example embodiment of FIG. 3, the signal integrity test pattern (e.g., stored in the test pattern register in the SI REGISTER 320) may include a bit pattern or sequence configured to test the signal integrity of a target pin. In an example, the bit pattern may be received in an external signal received through the SMBUS.

In the example embodiment of FIG. 3, the test pattern generator 330 may repeatedly generate a data pattern related to the signal integrity test pattern stored in the SI REGISTER 320 to perform the signal integrity test (e.g., received at S230 of FIG. 2) according to an input mode (e.g., received at S220 of FIG. 2) of the signal integrity test pattern (e.g., S210 of FIG. 2) stored in the SI REGISTER 320.

In the example embodiment of FIG. 3, the generated data pattern output by the test pattern generator 330 may be output to the memory interface pins of the memory 370. The generated data pattern output by the test pattern generator 330 may be applied to the memory interface pins of the memory 370 (e.g., a DRAM) via the data driver 340 and the command/address driver 350. In an example, the memory interface pins may include a data pin, an address pin, a command pin, etc.

In the example embodiment of FIG. 3, the test pattern generator 330 may interface with the memory 370 to provide the memory 370 with the data pattern generated by the test pattern generator 330. The data driver 340 may generate a data signal DQ, a data strobe signal DQS, a data mask signal DM, etc.

In the example embodiment of FIG. 3, the command/address driver C/A DRIVER 350 may interface with the memory 370 to provide the memory 370 with a command signal and/or an address signal corresponding to the data pattern generated by the test pattern generator 330. The command/address driver C/A DRIVER 350 may generate an address signal, a /RAS signal, a /CAS signal, a CS signal, etc.

In the example embodiment of FIG. 3, the system management bus interface SMBUS I/F 310, the data driver 340 and the command/address driver C/A driver 350 may be suitable for integration with an advanced memory buffer (AMB).

In the example embodiment of FIG. 3, the signal integrity test register SI REGISTER 320 may allow register settings to be controlled by external signals received through the system management bus interface SMBUS I/F 310. For example, the signal integrity test pattern and input mode may be configured via an external control of the signal integrity test register SI REGISTER 320.

In the example embodiment of FIG. 3, the signal integrity test pattern and/or an inverted version of the signal integrity test pattern may be repeatedly generated by the test pattern generator 330 to provide the generated test pattern to the memory 370 via the data driver 340 and the command/address driver C/A DRIVER 350. A desired test pattern may thereby be applied to the target pin to perform the signal integrity test.

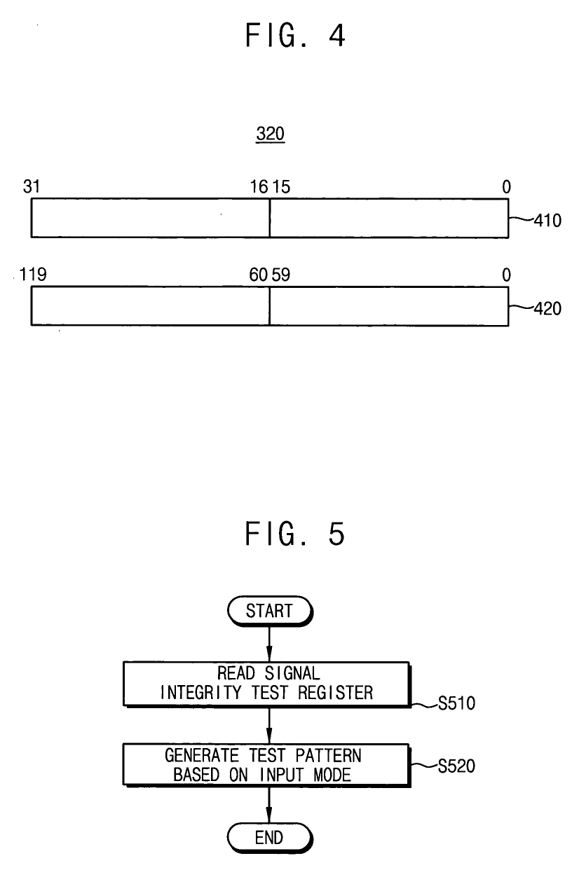

FIG. 4 is a schematic view illustrating a bit configuration of the signal integrity test register 320 of FIG. 3 according to another example embodiment of the present invention.

In the example embodiment of FIG. 4, the signal integrity test register 320 may include a test pattern register 410 and a test pattern input mode register 420. In an example, the test pattern register 410 may be a 32-bit register storing the signal integrity test pattern for testing the signal integrity of the target pin. It is understood, however, that other example embodiments of the present invention may include a test pattern register with other sizes (e.g., a 16-bit register, a 64-bit register, etc.). Further, in other example embodiments of the present invention, the bit length of the signal integrity test pattern may be adjusted by a user (e.g., via external control through the SMBUS I/F 310).

In the example embodiment of FIG. 4, the signal integrity test pattern stored in the test pattern register 410 may be transmitted in a first bit order (e.g., a normal bit order) from a least significant bit (LSB) to a most significant bit (MSB). Alternatively, the signal integrity test pattern in the test pattern register 410 may be transmitted in a second bit order (e.g., a reverse bit order) from the MSB to the LSB.

In the example embodiment of FIG. 4, the test pattern input mode register 420 may store the input mode associated with a manner of outputting the signal integrity test pattern to the target pin and/or to the remaining pins other than the target pin (e.g., based on whether the input mode designates the remaining pins to receive the signal integrity test pattern). For example, the input mode stored in the test pattern input mode register 420 may designate whether a non-inverted signal integrity test pattern may be applied to one or more of the memory interface pins and/or whether an inverted signal integrity test pattern may be provided to one or more of the memory interface pins.

In the example embodiment in FIG. 4, the test pattern input mode register 420 may include 120 memory interface pins. The 120 bits assigned for the test pattern input mode register 420 may correspond to each of the memory interface pins, respectively. It is understood that other example embodiments of the present invention may include any number of bits corresponding to any number of memory interface pins, and the 120 bits illustrated in FIG. 4 are given for example purposes only.

In the example embodiment of FIG. 4, first through eighth LSBs (e.g., bits numbering 0-7 in the test pattern input mode register 420 of FIG. 4) may correspond to address pins of a first memory, and a ninth LSB (e.g., a bit numbering 8 in the test pattern input mode register 420 of FIG. 4) may correspond to a chip select pin of the first memory. The first through eighth MSBs (e.g., bits numbering 112-119 in the test pattern input mode register 420 of FIG. 4) may correspond to data pins of the first memory. While not further described for the sake of brevity, each of the other bits of the test pattern input mode register 420 may be similarly assigned to other respective memory interface pins. However, it is understood that the example pin assignments given above are meant to represent examples only, and that any of the bits of the test pattern input mode register 420 may correspond to any of the memory interface pins in other example embodiments of the present invention.

In another example embodiment of the present invention, referring to FIG. 4, a signal applied to the target pin may be set to the same logic level (e.g., one of the first and second logic levels) as a logic level applied to pins other than the target pin (e.g., other memory interface pins). In an alternative example embodiment of the present invention, a signal applied to the target pin may not be set to the same logic level (e.g., one of the first and second logic levels) as a logic level applied to pins other than the target pin (e.g., other memory interface pins). In a further example, a pin to which the test pattern may be applied may be set to the first logic level (e.g., a higher logic level or logic “1”) and a pin to which the inverted test pattern may not be applied may be set to the second logic level (e.g., a lower logic level or logic “0”).

For example, if a second LSB of the test pattern input mode register 420 corresponds to a second data pin of the first memory pin as the target pin, the second LSB may be set to the first logic level (e.g., a higher logic level or logic “1”) and the remaining pins may be set to the second logic level (e.g., a lower logic level or logic “0”) such that the signal integrity test pattern may be applied only to the target pin while the remaining pins other than the target pin receive the inverted signal integrity test pattern.

In another example embodiment of the present invention, referring to FIG. 4, a bit of the test pattern input mode register 420 corresponding to a pin to which the test pattern is applied may be set to the second logic level (e.g., a lower logic level or logic “0”) and a bit corresponding to a pin to which an inverted test pattern is applied may be assigned to the first logic level (e.g., a higher logic level or logic “1”).

For example, if a second LSB of the test pattern input mode register 420 corresponds to a second data pin of the first memory pin as the target pin, the second LSB may be set to the second logic level (e.g., a lower logic level or logic “0”) and the remaining pins may be set to the first logic level (e.g., a higher logic level or logic “1”) such that the signal integrity test pattern may be applied only to the target pin while the remaining pins other than the target pin receive the inverted signal integrity test pattern.

In another example embodiment of the present invention, referring to FIG. 4, the signal integrity test pattern and/or the inverted test pattern may be provided to less than all of the memory interface pins. In an example, the inverted/non-inverted test pattern may be applied to a number of the, memory interface pins within a proximity of the target pin. For example, if one of the memory interface bits is either set or reset, the set/reset bit may be determined to be associated with the target pin such that the test pattern and/or the inverted test pattern may be provided to given number of bits in proximity of the determined target pin.

FIG. 5 is a flowchart diagram illustrating an operation of the test pattern generator 330 in FIG. 3 according to another example embodiment of the present invention.

In the example operation of FIG. 5, the test pattern generating unit 330 may read the signal integrity test register 320 (at S510). The signal integrity test register 320 may include the test pattern register and the test pattern input mode register, each of which may be read at S510.

In the example operation of FIG. 5, the test pattern generating unit 330 may repeatedly generate the signal integrity test pattern read from the signal integrity test register 320 (e.g., from the test pattern register) and/or the inverted signal integrity test pattern based on the input mode read from the signal integrity test register 320 (e.g., the test pattern input mode register) (at S520). The signal integrity test pattern and/or the inverted signal integrity test pattern may be received by the memory 370 on at least one of the plurality of memory interface pins.

In the example embodiment of FIG. 5, the test pattern generator 330 may read the signal integrity test pattern stored in the test pattern register 410 from the LSB to the MSB. Alternatively, in another example, the test pattern generator 330 may read the signal integrity test pattern stored in the test pattern register 410 from the MSB to the LSB.

In the example embodiment of FIG. 5, the signal integrity test pattern may be output from the test pattern generator 330 at the first logic level (e.g., a higher logic level or logic “1”), and the inverted signal integrity test pattern may be output at the second logic level (e.g., a lower logic level). Alternatively, in another example, the signal integrity test pattern may be output at the second logic level, and the inverted signal integrity test pattern may be output at the first logic level. In another example, the signal integrity test pattern and/or the inverted signal integrity test pattern may be output to less than all of the memory interface pins, for example, only pins in proximity of the target pin.

In another example embodiment of the present invention, the input mode for the signal integrity test pattern may be one of an even mode and an odd mode. In the example operation of the even mode, the signal integrity test pattern applied to the target pin and the signal integrity test pattern applied to other pins may be set to the same logic level (e.g., one of the first and second logic levels). In the example operation of the odd mode, the signal integrity test pattern applied to the target pin and the signal integrity test pattern applied to other pins may not be set to the same logic level.

TABLE 1

| Test Pattern Register Bit | Data |
|---|---|
| REG [31:24] | 11110110 |
| REG [23:16] | 10101010 |
| REG [15:8] | 11001111 |
| REG [7:0] | 10110101 |

TABLE 2

| Test Pattern Input | |
|---|---|
| Mode Register Bit | Data |
| REG [119:112] | 11111111 |
| REG [111:104] | 11111111 |
| REG [103:96] | 11111111 |
| REG [95:88] | 11111111 |
| REG [87:80] | 11111111 |
| REG [79:72] | 11111111 |
| REG [71:64] | 11111111 |
| REG [63:56] | 11111111 |
| REG [55:48] | 11111111 |
| REG [47:40] | 11111111 |
| REG [39:32] | 11111111 |
| REG [31:24] | 11111111 |
| REG [23:16] | 11111111 |
| REG [15:8] | 11111111 |
| REG [7:0] | 11111111 |

Table 1 and 2 (above) illustrate example bit configurations of the signal integrity test register 320 according to another example embodiment of the present invention. Referring to FIG. 4, Table 1 illustrates an example bit configuration of the test pattern register 410 in the signal integrity test register 320 and Table 2 illustrates an example bit configuration of the test pattern input mode register 420 in the signal integrity test register 320.

In the example embodiments of Table 1 and Table 2, the signal integrity test pattern may be applied according to the even mode where the bit pattern applied to the target pin and the bit pattern applied to other pins may be set to the same logic level. It is understood that Tables 1 and 2 are described with respect to the even mode for example purposes only, and other example embodiments of the present invention may have different tables related to the odd mode.

In the example embodiment of Table 2, the target pin for the signal integrity test may be set as a second LSB (e.g., REG [1]) and the test pattern generator 330 may output the test pattern to the memory interface pins corresponding to memory interface bits set to the first logic level (e.g., a higher logic level or logic “1”) and may output an inverted test pattern to the memory interface pins corresponding to memory interface bits set to the second logic level (e.g., a lower logic level or logic “0”).

In the example embodiment of Table 1, the signal integrity test pattern may be transmitted in an order from the MSB to the LSB. Alternatively, in another example, the signal integrity test pattern may be transmitted in an order from the LSB to the MSB. In another example, referring to Table 1, a bit for the target pin REG [1] may be set to the first logic level (e.g., a higher logic level or logic “1”) and all other pins may likewise be set to the first logic level. Thus, in the example embodiment of Table 1, each of the memory interface pins may receive the same logic level (e.g., the first logic level).

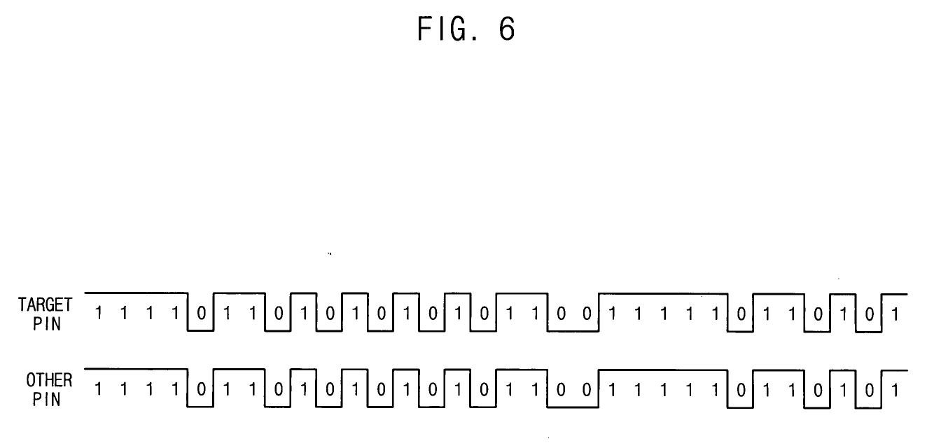

FIG. 6 is a waveform diagram of a data pattern applied to a memory interface pin using the signal integrity test register 320 of FIG. 3 in accordance with Table 1 and Table 2 according to another example embodiment of the present invention.

In the example embodiment of FIG. 6, the applied test pattern may be configured such that the same logic level (e.g., one of the first and second logic levels) may be applied to each of the memory interface pins, for example, when configured in accordance with Table 1 and Table 2. The signal integrity test may be performed by measuring the waveform at any one of the memory interface pins (e.g., the target pin).

TABLE 3

| Test Pattern Input | |
|---|---|
| Mode Register Bit | Data |
| REG [119:112] | 00000000 |
| REG [111:104] | 00000000 |
| REG [103:96] | 00000000 |
| REG [95:88] | 00000000 |
| REG [87:80] | 00000000 |
| REG [79:72] | 00000000 |
| REG [71:64] | 00000000 |
| REG [63:56] | 00000000 |
| REG [55:48] | 00000000 |
| REG [47:40] | 00000000 |
| REG [39:32] | 00000000 |
| REG [31:24] | 00000000 |
| REG [23:16] | 00000000 |
| REG [15:8] | 00000000 |
| REG [7:0] | 00000010 |

Table 3 illustrates an example bit configuration of the test pattern input mode register 420 of the signal integrity test register 320 according to another example embodiment of the present invention.

In the example embodiment of Table 3, the example bit configuration of the test pattern register 410 of the signal integrity test register 320 may be set in accordance with Table 1. The signal integrity test pattern may be applied in accordance with the odd mode where the signal integrity test pattern applied to the target pin may differ from the signal integrity test pattern applied to other pins. Further, similar to Tables 1 and 2, the target pin for the signal integrity test in Table 3 may be set as the second LSB (e.g., REG[1]) and the test pattern generator 330 may output the signal integrity test pattern to the memory interface pins corresponding to a bit set to the first logic level (e.g., a higher logic level or logic “1”) and may output an inverted signal integrity test pattern to the memory interface pins corresponding to a bit set to the second logic level (e.g., a lower logic level or logic “0”).

In the example embodiment of Table 3, a bit for the target pin REG1] may be set to the first logic level and pins other than the target pin REG[1] may be set to the second logic level. It is understood that other example embodiments may include a target pin other than REG[1] and that other example embodiments may be configured for operation in accordance with the even mode.

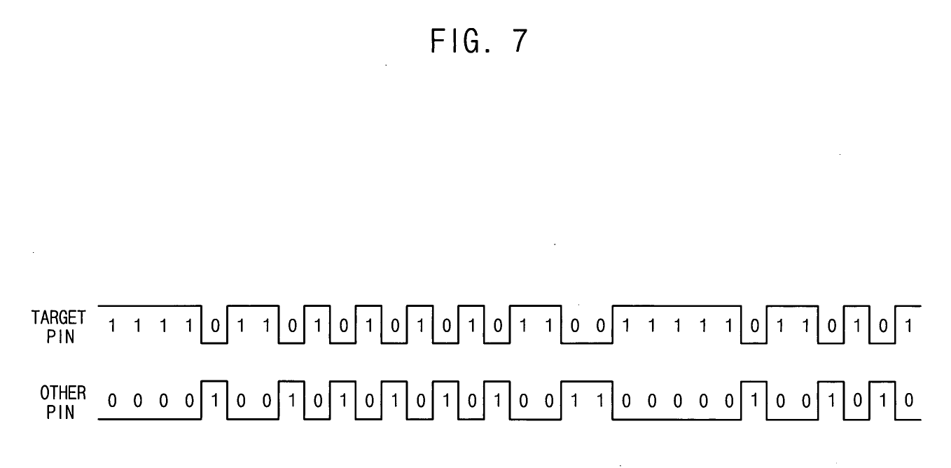

FIG. 7 is a waveform diagram of a data pattern applied to a memory interface pin using the signal integrity test register 320 of FIG. 3 in accordance with Table 1 and Table 3 according to another example embodiment of the present invention.

In the example embodiment of FIG. 7, the signal integrity test pattern may be applied to the target pin and pins other than the target pin at opposing logic levels. Thus, the signal integrity test may be performed by measuring a waveform (e.g., with an oscilloscope) at one of the memory interface pins (e.g., the target pin).

As described above, example embodiments of the present invention may be applied in accordance with one of the even mode and the odd mode, for example, as designated by the test pattern input mode register 420. Other example embodiments of the present invention, however, may not be limited to the above-described even and odd modes. For example, instead of matching a logic level to the target pin or opposing a logic level of the target pin, each of the respective memory interface pins may be individually controlled (e.g., not based on the target pin logic level). For example, pins in proximity of the target pin may operate in accordance with the even mode while pins not in the proximity of the target pin may operate in accordance with the odd mode.

In another example embodiment of the present invention, any type of testing of the signal integrity of a target pin or pins may be employed such that a separate register of a memory module may be used to receive a test pattern (e.g., a bit sequence) and an input mode of the test pattern to perform the testing for the signal integrity of the target pin or pins.

Example embodiments of the present invention being thus described, it will be obvious that the same may be varied in many ways. For example, it is understood that the above-described first and second voltage levels may correspond to a higher level (e.g., logic “1”) and a lower logic level (e.g., logic “0”), respectively, in an example embodiment of the present invention. Alternatively, the first and second voltage levels may correspond to the lower logic level (e.g., logic “0”) and the higher logic level (e.g., logic “1”), respectively, in other example embodiments of the present invention.

Such variations are not to be regarded as departure from the spirit and scope of example embodiments of the present invention, and all such modifications as would be obvious to one skilled in the art are intended to be included within the scope of the following claims.

What is claimed:

1. A method of testing a memory module, comprising:
receiving a test pattern and an associated input mode, the input mode indicating a manner of applying the received test pattern; and
applying an output test pattern to at least one of a plurality of memory interface pins in accordance with the input mode.

2. The method of claim 1, further comprising:
storing the received test pattern in a first register of the memory module.

3. The method of claim 1, wherein the at least one of the plurality of memory interface pins includes a target pin.

4. The method of claim 1, wherein the output test pattern includes at least one of the received test pattern and an inverted version of the received test pattern.

5. The method of claim 3, wherein the received test pattern includes a bit sequence with a number of bits sufficient to test signal integrity of the target pin.

6. The method of claim 5, wherein the length of the bit sequence is adjusted based on at least one control signal received from an external source.

7. The method of claim 3, wherein the at least one of the plurality of memory interface pins further includes at least one pin other than the target pin.

8. The method of claim 7, wherein the applying includes applying the received test pattern to the target pin and applying an inverted version of the received test pattern to the at least one pin other than the target pin.

9. The method of claim 2, further comprising:
storing the received associated input mode in a second register of the memory module, the second register including a number of bits corresponding to a number of the plurality of memory interface pins.

10. The method of claim 9, wherein the applying includes applying the received test pattern to memory interface pins corresponding to bits of the second register assigned to a first logic level, and applying an inverted version of the received test pattern to memory interface pins corresponding to bits of the second register assigned to a second logic level.

11. The method of claim 1, wherein the test pattern and the associated input mode are received through a system management bus.

12. The method of claim 1, wherein the memory module is a fully buffered dual in-line memory module.

13. A buffer of a memory module, comprising:
a test register configured to receive and store a test pattern and an associated input mode, the input mode indicating a manner of applying the test pattern; and
a test pattern generator configured to repeatedly generate an output test pattern based on the associated input mode.

14. The buffer of claim 13, wherein the generated output test pattern includes at least one of the stored test pattern and an inverted version of the stored test pattern.

15. The buffer of claim 13, wherein the test pattern generator applies the repeatedly generated output test pattern to a target pin.

16. The buffer of claim 13, wherein the test register includes a test pattern register configured to store the test pattern and a test pattern input mode register configured to store the associated input mode.

17. The buffer of claim 13, wherein the stored test pattern includes a bit sequence with a number of bits sufficient for testing signal integrity of a target pin.

18. The buffer of claim 16, wherein the test pattern input mode register has a register setting which instructs the test pattern generator to apply the output test pattern to both the target pin and at least one pin other than the target pin.

19. The buffer of claim 13, wherein the output test pattern includes the received test pattern being applied to a target pin and an inverted version of the received test pattern being applied to at least one pin other than the target pin.

20. The buffer of claim 16, wherein the test pattern input mode register includes a number of bits corresponding to a number of memory interface pins of the memory module.

21. The buffer of claim 16, wherein the output test pattern includes the received test pattern being applied to memory interface pins corresponding to bits of the test pattern input mode register assigned to a first logic level, and the output test pattern further includes an inverted version of the received test pattern being applied to memory interface pins corresponding to bits of the test pattern input mode register assigned to a second logic level.

22. The buffer of claim 13, wherein the test register receives the test pattern and the associated input mode through a system management bus.

23. The buffer of claim 14, wherein the memory module is a fully buffered dual in-line memory module.

24. A memory module, comprising:
the buffer of claim 13; and
a memory receiving the output test pattern from the buffer.

25. The memory module of claim 24, wherein the memory is a dynamic random access memory (DRAM).

26. A method of testing a memory module with the buffer of claim 13.
